(19) United States
(12) Patent Application Publication
(10) Pub. No.: US 2007/0080141 A1
(43) Pub. Date: Apr. 12, 2007

(54) Low-voltage inductively coupled source for plasma processing

(75) Inventors: John M. White, Hayward, CA (US); Carl Sorensen, Morgan Hill, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/245,557

(22) Filed: Oct. 7, 2005

(51) Int. Cl. B44C 1/22; C23F 1/00; B01J 19/08; C23C 16/00

(52) U.S. Cl. 216/68; 118/723 I; 156/345.48; 427/457

(57) ABSTRACT

A chamber for plasma processing a substrate. The chamber includes one or more chamber walls defining a plasma processing region and an RF transmitting device configured to transmit RF energy to the plasma processing region. The RF transmitting device comprises a first coil portion and a second coil portion connected in parallel. Each of the first coil portion and the second coil portion is a half turn coil and the voltage at an input of the first coil portion and the voltage at an input of the second coil portion are about the same.

### BACKGROUND OF THE INVENTION

1. Field of the Invention

Embodiments of the present invention generally relate to an apparatus and method used for fabricating electronic devices using a plasma processing system.

2. Description of the Related Art

In the fabrication of flat panel displays (FPD), thin film transistors (TFT) and liquid crystal cells, metal interconnects and other features are formed by depositing and removing multiple layers of conducting, semiconducting and dielectric materials on a glass substrate. The various features formed are integrated into a system that is collectively used to create, for example, active matrix display screens in which display states are electrically created in individual pixels on the FPD. Processing techniques used to create the FPD include plasma-enhanced chemical vapor deposition (PECVD), physical vapor deposition (PVD), etching, and the like. Plasma processing is particularly well suited for the production of flat panel displays because of the relatively lower processing temperatures required to deposit film and the good film quality resulting therefrom.

Some plasma processing chambers may include an RF coil coupled to an RF power source for generating and controlling plasma inside the processing chamber. However, the plasma may become unstable due to capacitive coupling between the RF coil and the plasma.

Therefore, a need exists in the art for a new method and apparatus for generating and controlling plasma inside the processing chamber that minimizes plasma instability due to capacitive coupling between the RF coil and the plasma.

### SUMMARY OF THE INVENTION

One or more embodiments of the invention are directed to a chamber for plasma processing a substrate. The chamber includes one or more chamber walls defining a plasma processing region and an RF transmitting device configured to transmit RF energy to the plasma processing region. The RF transmitting device comprises two or more coil portions connected in parallel.

One or more embodiments of the invention are also directed to a chamber for plasma processing a substrate. The chamber includes one or more chamber walls defining a plasma processing region and an RF transmitting device configured to transmit RF energy to the plasma processing region. The RF transmitting device comprises a first coil portion and a second coil portion connected in parallel. Each of the first coil portion and the second coil portion is a half turn coil and the voltage at an input of the first coil portion and the voltage at an input of the second coil portion are about the same.

One or more embodiments of the invention are also directed to a chamber for plasma processing a substrate. The chamber includes one or more chamber walls defining a plasma processing region and an RF transmitting device configured to transmit RF energy to the plasma processing region. The RF transmitting device comprises a first coil portion and a second coil portion connected in parallel, wherein each of the first coil portion and the second coil portion is a half turn coil. The chamber further includes an impedance pre-match network coupled to the RF transmitting device and an impedance match network coupled to the impedance pre-match network. The impedance pre-match network is configured to receive a single ended input from the impedance match network and provide a double ended output to the RF transmitting device.

One or more embodiments of the invention are also directed to a method for transmitting RF energy to a plasma processing region. The method includes providing an RF transmitting device having a first coil portion connected to a second coil portion connected in parallel. The RF transmitting device is coupled to a chamber having one or more walls defining the plasma processing region. The method further includes applying RF power to the first coil portion and applying RF power to the second coil portion.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a schematic cross-sectional view of a plasma processing chamber that may be used in connection with one or more embodiments of the invention.

FIGS. 1B and 1C are cross-sectional views of an inductively coupled source assembly illustrated in FIG. 1A.

FIG. 2 illustrates a substrate support of the plasma processing chamber illustrated in FIG. 1A in a transfer position.

FIG. 3 illustrates a top view of a plasma processing chamber having an RF coil configuration in accordance with one or more embodiments of the invention.

FIG. 4 illustrates an RF coil configuration having four quarter turn coil portions in accordance with one or more embodiments of the invention.

FIG. 5 illustrates a schematic diagram of a plasma processing chamber having an RF coil configuration in accordance with one or more embodiments of the invention.

FIG. 6 illustrates the phase relationships between the voltages at inputs and outputs illustrated in FIG. 5.

FIG. 7 illustrates a top view of a plasma processing chamber that may be used in connection with one or more embodiments of the invention.

FIG. 8 illustrates an isometric view of a plasma processing chamber that may be used in connection with one or more embodiments of the invention.

FIG. 9 illustrates a cluster tool that may be used in connection with one or more embodiments of the invention.

### DETAILED DESCRIPTION

Various embodiments of the invention are generally directed to an apparatus and method for processing a surface of a substrate using an inductively coupled high density plasma. In general, various aspects of the present invention may be used for flat panel display processing, semiconductor processing, solar cell processing, or any other substrate processing. Embodiments of the invention are illustratively described below with reference to a chemical vapor deposition system for processing large area substrates, such as a plasma enhanced chemical vapor deposition (PECVD) system, available from AKT, a division of Applied Materials, Inc., Santa Clara, Calif. However, it should be understood that the apparatus and method may have utility in other system configurations, including those systems configured to process round substrates.

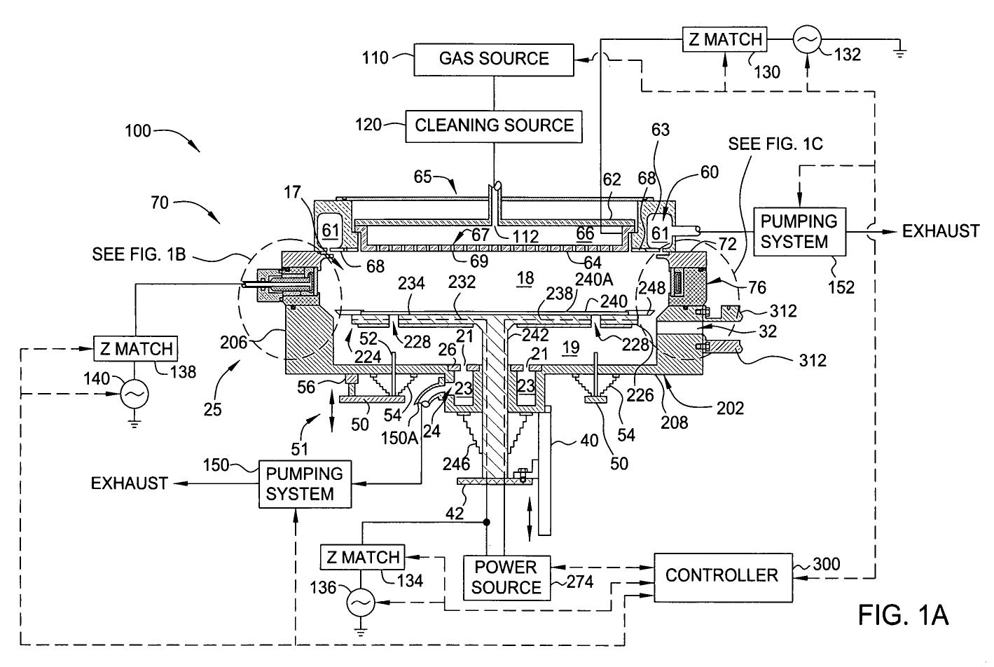

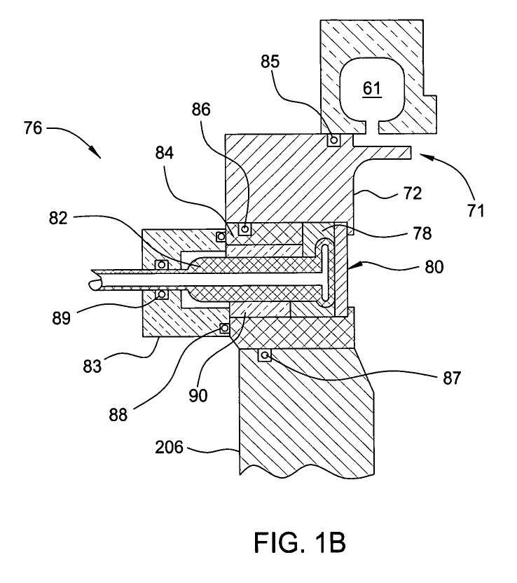

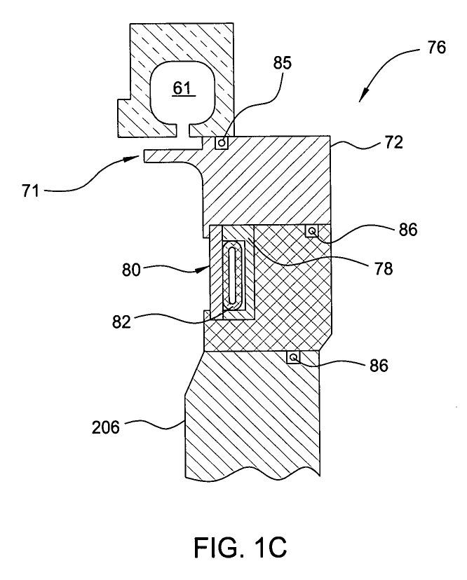

FIG. 1A illustrates a schematic cross-sectional view of a plasma processing chamber 100 that may be used in connection with one or more embodiments of the invention. The plasma processing chamber 100 generally includes a gas distribution assembly 64, an inductively coupled source assembly 70, and a lower chamber assembly 25. A chamber volume 17, which is made up of a process volume 18 and a lower volume 19, defines a region in which the plasma processing may occur. The chamber volume 17 is enclosed by the gas distribution assembly 64, the inductively coupled source assembly 70, and the lower chamber assembly 25.

The lower chamber assembly 25 generally includes a substrate lift assembly 51, a substrate support 238 and a processing chamber base 202. The processing chamber base 202 has chamber walls 206 and a chamber bottom 208 that partially define a lower volume 19. The processing chamber base 202 is accessed through the access port 32 in the chamber walls 206. The access port 32 defines the region through which a substrate 240 can be moved in and out of the processing chamber base 202. The chamber walls 206 and chamber bottom 208 may be fabricated from a unitary block of aluminum or other material(s) compatible with processing.

A temperature controlled substrate support 238 is connected to the processing chamber base 202. The substrate support 238 supports a substrate 240 during processing. The substrate support 238 may include an aluminum body 224 that encapsulates at least one embedded heater 232. The embedded heater 232, such as a resistive heating element, is disposed in the substrate support 238. The embedded heater 232 is coupled to a power source 274, which may controllably heat the substrate support 238 and the substrate 240 positioned thereon to a predetermined temperature by use of a controller 300. Typically, in most CVD processes, the embedded heater 232 maintains the substrate 240 at a uniform temperature range between about 60° C. for plastic substrates to about 550° C. for glass substrates.

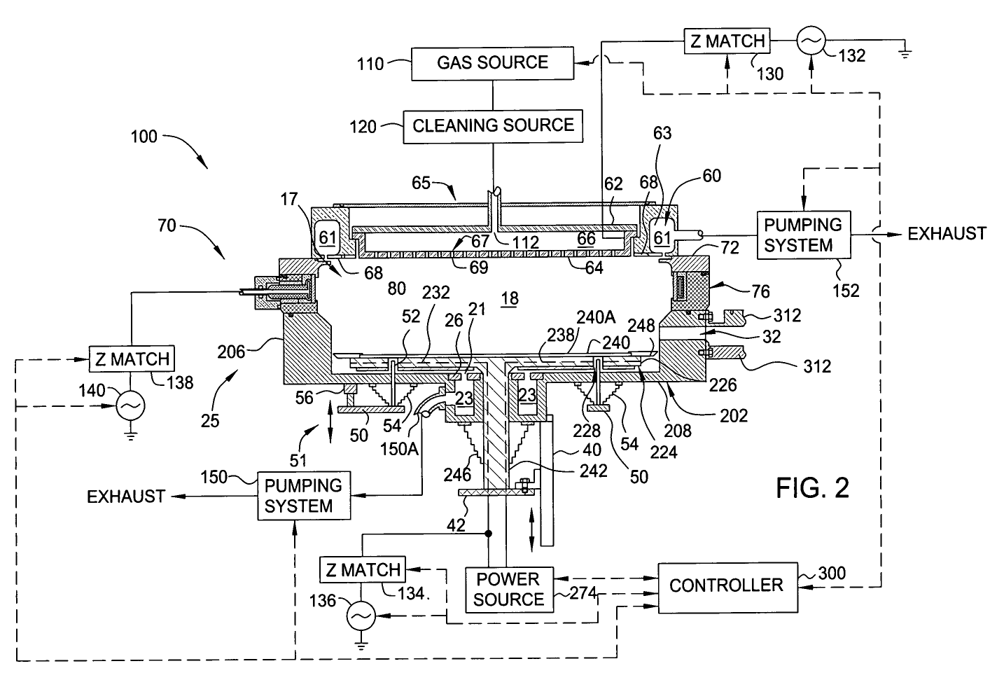

Generally, the substrate support 238 has a back side 226, a front side 234 and a stem 242. The front side 234 supports the substrate 240, while the stem 242 is coupled to the back side 226. The stem base 42 attached to the stem 242 is connected to a lift assembly 40 that moves the substrate support 238 between various positions. The transfer position, shown in FIG. 2, allows the system robot (not shown) to freely enter and exit the plasma processing chamber 100 without interference with the substrate support 238 and/or the lift pins 52. The stem 242 additionally provides a conduit for electrical and thermocouple leads between the substrate support 238 and other components of the cluster tool 910. The lift assembly may comprise a pneumatic or motorized lead-screw type lift assembly commonly used in the art to supply the force necessary to counteract gravity and atmospheric pressure forces acting on the substrate support 238 when the plasma processing chamber 100 is under vacuum, and to accurately position the support assembly in the plasma processing chamber 100.

A bellows 246 is coupled between substrate support 238 (or the stem 242) and the chamber bottom 208 of the processing chamber base 202. The bellows 246 provides a vacuum seal between the chamber volume 17 and the atmosphere outside the processing chamber base 202, while facilitating vertical movement of the substrate support 238.

The substrate support 238 additionally supports a substrate 240 and a circumscribing shadow frame 248. Generally, the shadow frame 248 prevents deposition on the edge of the substrate 240 and on the substrate support 238.

The substrate support 238 has a plurality of holes 228 disposed therethrough to accept a plurality of lift pins 52. The lift pins 52 are typically made from ceramic, graphite, ceramic coated metal, or stainless steel. The lift pins 52 may be actuated relative to the substrate support 238 and process chamber base 202 by use of a lift plate 50 that can move the lift pins 52 from a retracted position (as shown in FIG. 1A) to a raised position (not shown). The lift bellows 54 attached to each of the lift pins 52 and the chamber bottom 208, are used to isolate the lower volume 19 from the atmosphere outside of the plasma process chamber 100, while also allowing the lift pins 52 to move from the retracted position (as shown in FIG. 1A) to the raised position (not shown). The lift plate 50 may be actuated by use of a lift actuator 56. When the lift pins 52 are in the raised position and the substrate support 238 is in the transfer position, the substrate 240 is lifted above the top edge of the access port 32 so that the system robot can enter and exit from the plasma processing chamber 100.

The lid assembly 65 typically includes an entry port 112 through which process gases, provided by the gas source 110, may be introduced into the process volume 18 after passing through the gas distribution plate 64. Proper control and regulation of the gas flows from the gas source 110 to the entry port 112 are performed by mass flow controllers (not shown) and a controller 300. The gas source 110 may include a plurality of mass flow controllers (not shown). The term “mass flow controllers”, as used herein, refers to any control valves capable of providing rapid and precise gas flow to the plasma processing chamber 100. The entry port 112 allows process gases to be introduced and uniformly distributed in the plasma processing chamber 100. Additionally, the entry port 112 may optionally be heated to prevent condensation of any reactive gases within the manifold.

The entry port 112 is also coupled to a cleaning source 120. The cleaning source 120 typically provides a cleaning agent, such as disassociated fluorine, that is introduced into the process volume 18 to remove deposition by-products and stray deposited material left over after the completion of prior processing steps.

The lid assembly 65 provides an upper boundary to the process volume 18. The lid assembly 65 may be removed from the chamber base 202 and/or the inductively coupled source assembly 70 to service components in the plasma processing chamber 100. Typically, the lid assembly 65 is fabricated from aluminum (Al) or an anodized aluminum body.

The lid assembly 65 may include an upper pumping plenum 63 coupled to an external vacuum pumping system 152. The upper pumping plenum 63 may be utilized to uniformly evacuate the gases and processing by-products from the process volume 18. The upper pumping plenum 63 is generally formed within, or attached to, the chamber lid 60 and covered by a plate 68 to form the pumping channel 61. To assure uniform evacuation of the process volume 18, a gap is formed between the plate 68 and chamber lid 60 to create a small restriction to gas flow into the pumping channel 61. A shadow feature 71 formed on the lid support member 72 of the inductively coupled source assembly 70 may also be used to supply an additional restriction to further assure uniform evacuation of the process volume 18. The vacuum pumping system 152 may include a vacuum pump, such as a turbo pump, rough pump, and/or Roots Blower™ pump, as required to achieve the desired chamber processing pressures.

A lower pumping plenum 24, disposed in the lower chamber assembly 25, may be used to uniformly evacuate the gases and processing by-products from the process volume 18 by use of a vacuum pumping system 150. The lower pumping plenum 24 is generally formed within or attached to the chamber bottom 208. The lower pumping plenum 24 may be covered by a plate 26 to form an enclosed pumping channel 23. The plate 26 generally contains a plurality of holes 21 (or slots) for creating a small restriction to gas flow into the pumping channel 23, and thereby assuring uniform evacuation of the chamber volume 17. The pumping channel 23 is connected to the vacuum pumping system 150 through a pumping port 150A. The vacuum pumping system 150 may include a vacuum pump, such as a turbo pump, rough pump, and/or Roots Blower™ pump. The lower pumping plenum 24 may be symmetrically distributed about the center of the processing chamber to ensure even gas evacuation from the process volume 18. Alternatively, the lower pumping plenum 24 may be non-symmetrically positioned (not shown) in the lower chamber assembly 25.

The lower pumping plenum 24 and the upper pumping plenum 63 may be both used to evacuate the process volume 18. As such, the relative flow rate of gas removed from the process volume 18, by use of vacuum pumping system 152, and from the lower volume 19, by use of vacuum pumping system 150, may be optimized to improve plasma processing results and reduce the leakage of the plasma and processing by-products into the lower volume 19. Reducing the leakage of the plasma and processing by-products may reduce the amount of stray deposition on the lower chamber assembly 25 components and thus reduce the clean time and/or the frequency of using the cleaning source 120 to remove these unwanted deposits.

A gas distribution plate 64 is coupled to a top plate 62 of the lid assembly 65. The shape of the gas distribution plate 64 is typically configured to substantially follow the profile of the substrate 240. The gas distribution plate 64 includes a perforated area 67, through which process and other gases supplied from the gas source 110 are delivered to the process volume 18. The perforated area 67 of the gas distribution plate 64 is configured to provide uniform distribution of gases passing through the gas distribution plate 64 into the process volume 18. Gas distribution plates that may be adapted to benefit from the invention are described in commonly assigned U.S. patent application Ser. No. 10/337,483, filed Jan. 7, 2003 by Blonigan et al.; U.S. Pat. No. 6,477,980, issued Nov. 12, 2002 to White et al.; and U.S. patent application Ser. Nos. 10/417,592, filed Apr. 16, 2003 by Choi et al., which are hereby incorporated by reference in their entireties.

The gas distribution plate 64 may be formed from a single unitary member. The gas distribution plate 64 may also be made from two or more separate pieces. A plurality of gas passages 69 are formed through the gas distribution plate 64 to allow a desired distribution of the process gases to pass through the gas distribution plate 64 and into the process volume 18. A plenum 66 is formed between the gas distribution plate 64 and the top plate 62. The plenum 66 allows gases flowing into the plenum 66 from the gas source 110 to uniformly distribute across the width of the gas distribution plate 64 and flow uniformly through the gas passages 69. The gas distribution plate 64 is typically fabricated from aluminum (Al), anodized aluminum, or other RF conductive material. The gas distribution plate 64 is electrically isolated from the chamber lid 60 by an electrical insulation piece (not shown).

Referring to FIGS. 1A, 1B and 1C, the inductively coupled source assembly 70 includes an RF coil 82, a support structure 76, a cover 80, and various insulating pieces (e.g., an inner insulation 78, an outer insulation 90, etc.) The supporting structure 76 includes a supporting member 84 and a lid support member 72, which are grounded metal parts that support the lid assembly 65's components. The RF coil 82 is supported and surrounded by a number of components which prevent the RF power delivered to the coil from the RF power source 140 from arcing to the support structure 76 or incurring significant losses to the grounded chamber components (e.g., processing chamber base 202, etc.). A cover 80, which is a thin continuous ring, band or array of overlapping sections, is attached to the supporting structure 76 components. The cover 80 is intended to shield the RF coil 82 from interacting with the plasma deposition chemistries or from being bombarded by ions or neutrals generated during plasma processing or by chamber cleaning chemistries. The cover 80 is made from a ceramic material (e.g., alumina or sapphire) or other process-compatible dielectric material. Also, various insulating pieces, for example, the inner insulation 78 and the outer insulation 90, are used to support and isolate the RF coil 82 from the electrically grounded supporting structure 76. The insulating pieces are generally made from an electrically insulating materials, for example, Teflon® polymer or ceramic materials. A vacuum feedthrough 83 attaches to the supporting structure 76 to hold and support the RF coil 82 and prevent atmospheric leakage into an evacuated process volume 18. The supporting structure 76, the vacuum feedthrough 83 and the various 0-rings 85, 86, 87, 88 and 89 form a vacuum tight structure that supports the RF coil 82 and the gas distribution assembly 64 and allows the RF coil 82 to communicate with the process volume 18 with no conductive barriers to inhibit the RF generated fields.

The RF coil 82 is connected to an RF power source 140 through RF impedance match networks 138. In this configuration, the RF coil 82 acts as an inductively coupled RF energy transmitting device that can generate and control the plasma generated in the process volume 18. Dynamic impedance matching may be provided to the RF coil 82. By use of the controller 300, the RF coil 82, which is mounted at the periphery of the process volume 18, is able to control and shape a plasma generated near the substrate surface 240A.

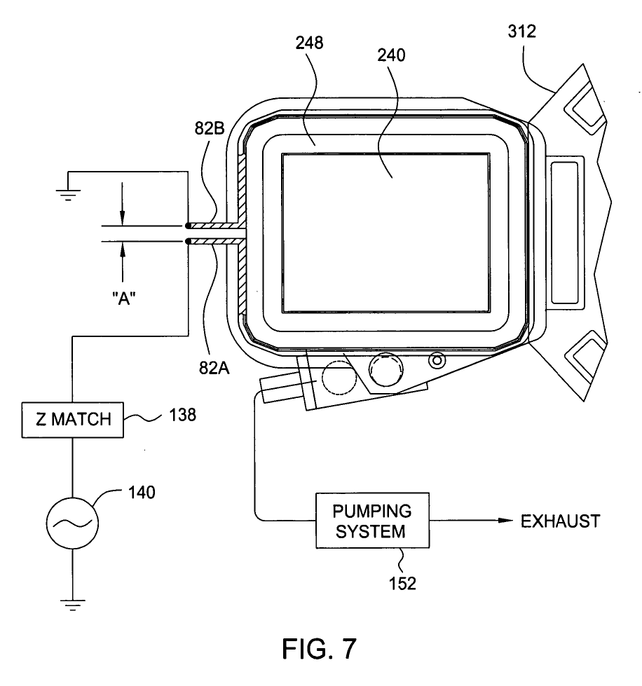

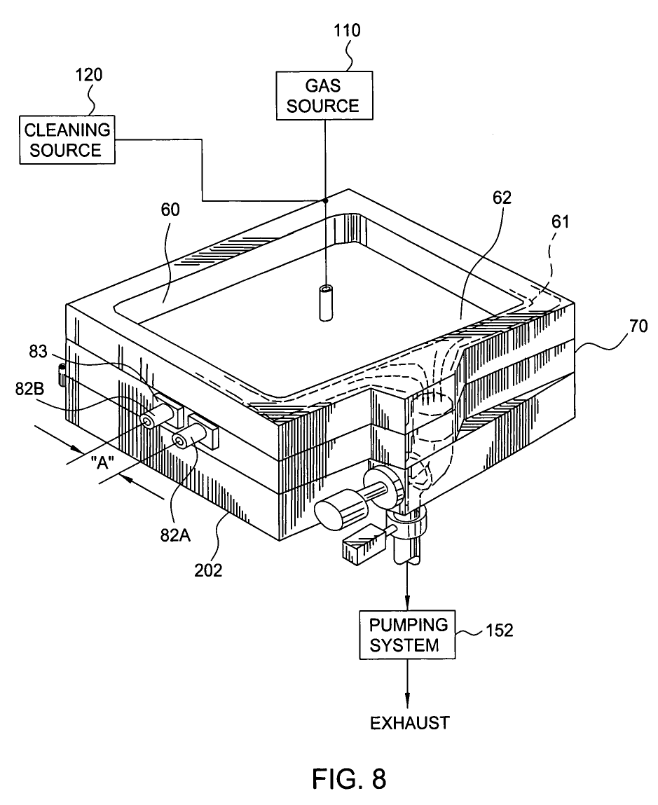

The RF coil 82 may be a single turn coil. As such, the coil ends of a single turn coil may affect the uniformity of the plasma generated in the plasma processing chamber 100. When it is not practical or desired to overlap the ends of the coil, a gap region “A”, as shown in FIGS. 7 and 8, may be left between the coil ends. The gap region “A,” due to the missing length of coil and RF voltage interaction at the input end 82A and output end 82B of the coil, may result in weaker RF generated magnetic field near the gap “A”. The weaker magnetic field in this region can have a negative effect on the plasma uniformity in the chamber. To resolve this possible problem, the reactance between the RF coil 82 and ground can be continuously or repeatedly tuned during processing by use of a variable inductor, which shifts or rotates the RF voltage distribution, and thus the generated plasma, along the RF coil 82, to time average any plasma non-uniformity and reduce the RF voltage interaction at the ends of the coil. An exemplary method of tuning the reactance between the RF coil 82 and ground, to shift the RF voltage distribution in a coil, is further described in U.S. patent application U.S. Pat. No. 6,254,738, entitled “Use of Variable Impedance Having Rotating Core to Control Coil Sputtering Distribution”, issued on Jul. 3, 2001, which is incorporated herein by reference. As a consequence, the plasma generated in the process volume 18 is more uniformly and axially symmetrically controlled, through time-averaging of the plasma distribution by varying the RF voltage distribution. The RF voltage distributions along the RF coil 82 can influence various properties of the plasma including the plasma density, RF potential profiles, and ion bombardment of the plasma-exposed surfaces including the substrate 240.

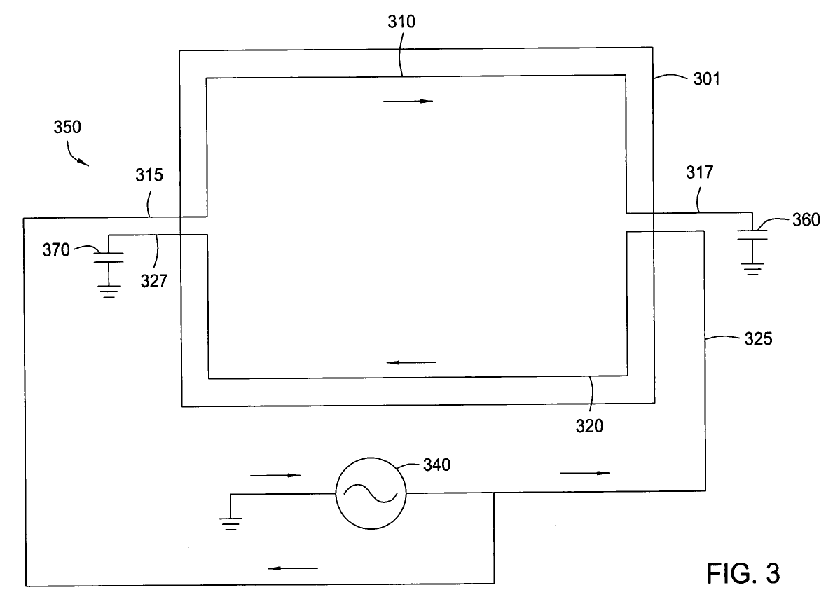

FIG. 3 illustrates a top view of a plasma processing chamber 301 having an RF coil configuration 350 in accordance with one or more embodiments of the invention. The RF coil configuration 350 includes a first coil portion 310 coupled to a second coil portion 320 in parallel. The first coil portion 310 is a half turn coil and the second coil portion 320 is also a half turn coil, the total of which forms the single turn RF coil configuration 350. The first coil portion 310 includes an input 315 coupled to an RF power source 340 and an output 317 coupled to a capacitor 360, which is coupled to ground. The voltage at input 315 is 180 degrees out of phase with the voltage at output 317. Likewise, the second coil portion 320 includes an input 325 coupled to the RF power source 340 and an output 327 coupled to a capacitor 370, which is coupled to ground. The voltage at input 325 is 180 degrees out of phase with the voltage at output 327. The arrows indicate the flow of current along the RF coil configuration 350. In one embodiment, the voltage at input 315 is half the voltage at the input of a single turn RF coil, e.g., RF coil 82 in FIG. 1B and 1C. Likewise, the voltage at input 325 is half the voltage at the input of the single turn RF coil, e.g., RF coil 82. As such, the voltage at input 315 and the voltage at input 325 are about the same. In this manner, the total input voltage to the RF coil configuration 350 remains about the same as the input voltage to the RF coil 82. However, the capacitive coupling voltage to the plasma using the RF coil configuration 350 is reduced to about half the capacitive coupling voltage to the plasma using the single RF coil 82, which in turn reduces the likelihood of arcing. The RF coil configuration 350 is not limited to two half turn coil portions. In other embodiments, the RF coil configuration 350 may include four quarter turn coil portions, eight one eighth turn coil portions and so on.

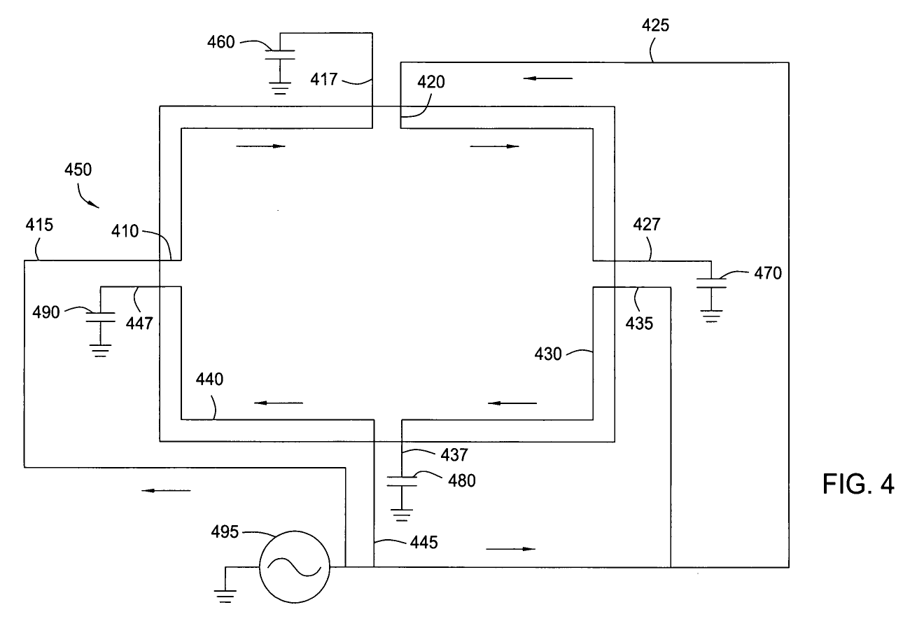

For instance, FIG. 4 illustrates an RF coil configuration 450 having four quarter turn coil portions in accordance with one or more embodiments of the invention. The RF coil configuration 450 includes a first coil portion 410, a second coil portion 420, a third coil portion 430 and a fourth coil portion 440, all of which are coupled in parallel to each other. Each coil portion is a quarter turn coil. The first coil portion 410 includes an input 415 coupled to an RF power source 495 and an output 417 coupled to a capacitor 460, which is coupled to ground. Likewise, the second coil portion 420 includes an input 425 coupled to the RF power source 495 and an output 427 coupled to a capacitor 470, which is coupled to ground. The third coil portion 430 includes an input 435 coupled to the RF power source 495 and an output 437 coupled to a capacitor 480, which is coupled to ground. The fourth coil portion 440 includes an input 445 coupled to the RF power source 495 and an output 447 coupled to a capacitor 490, which is coupled to ground. The arrows indicate the flow of current along the RF coil configuration 450.

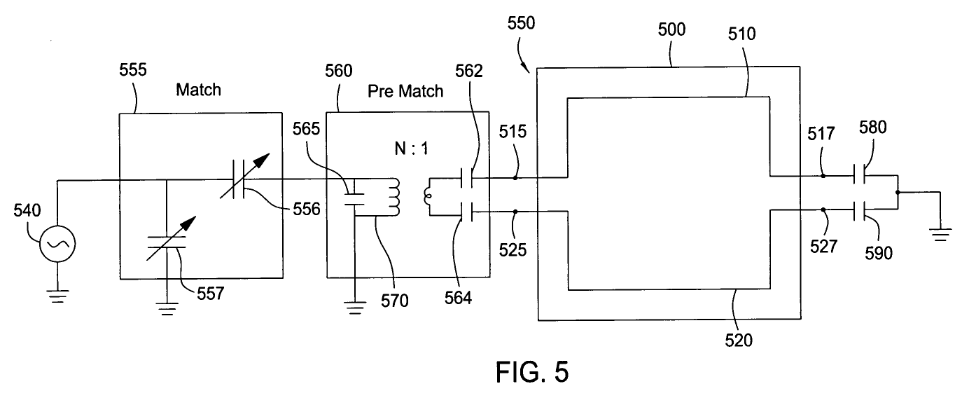

FIG. 5 illustrates a schematic diagram of a plasma processing chamber 500 having an RF coil configuration 550 in accordance with one or more embodiments of the invention. The RF coil configuration 550 includes a first coil portion 510 and a second coil portion 520 in parallel with each other. The first coil portion 510 is a half turn coil and the second coil portion 520 is also a half turn coil.

The RF coil configuration 550 is being driven by an RF power source 540 via a match network 555 and a pre-match network 560. The match network 555 includes variable capacitors 556 and 557. The match network 555 may be any impedance match network commonly known by persons of ordinary skill in the art.

The pre-match network 560 is configured to receive a single ended input from the match network 555 and provide a double ended output to the RF coil configuration 550—one at an input 515 and the other one at an input 525. The pre-match network 560 includes a transformer 570 to increase the impedance of the RF coil configuration 550 by a factor of N². In this manner, the pre-match network 560 is configured to transform the impedance of the RF coil configuration 550 to a level of impedance operable by the match network 555. In one embodiment, the pre-match network 560 further includes capacitors 562, 564 and 565.

The first coil portion 510 further includes an output 517 coupled to a capacitor 580, which is coupled to ground. The second coil portion 520 further includes an output 527 coupled to a capacitor 590, which is coupled to ground. As such, capacitors 580 and 590 may function as a reactive element.

In one embodiment, each of capacitor 562, 564, 580 and 590 has about the same amount of capacitance. The resulting capacitance of capacitor 562 in combination with capacitor 580 resonates with the inductance of the first coil portion 510. Likewise, the resulting capacitance of capacitor 564 in combination with capacitor 590 resonates with the inductance of the second coil portion 520. Further, capacitor 565 may be used to counteract any leakage inductance caused by imperfect coupling within the transformer 570.

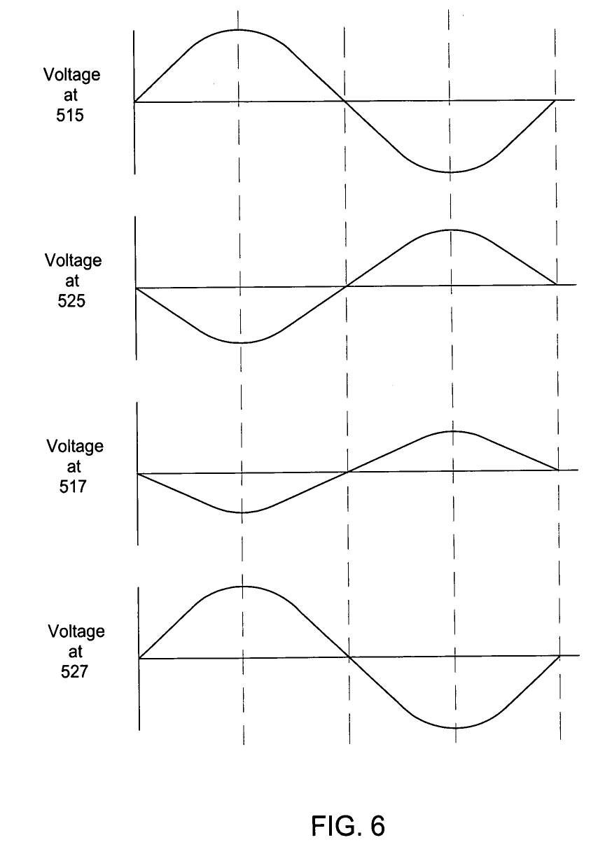

The voltage amplitude at inputs 515 and 525 and outputs 517 and 527 are about the same. However, the voltage at input 515 is 180 degrees out of phase with the voltage at output 517 and the voltage at input 525 is also 180 degrees out of phase with the voltage at output 527. FIG. 6 illustrates the phase relationships between the voltages at inputs 515, 525 and outputs 517 and 527. In this manner, the voltages at inputs 515, 525 and outputs 517 and 527 are as low as they can possibly be with respect to the plasma, thereby allowing the onset of plasma instability caused by capacitive coupling between the RF coil and plasma to begin at a higher input RF power level.

Referring back to FIG. 1A, the gas distribution plate 64 may be RF biased so that a plasma generated in the process volume 18 may be controlled and shaped by use of an attached impedance match element 130, an RF power source 132 and the controller 300. The RF biased gas distribution plate 64 acts as a capacitively coupled RF energy transmitting device that can generate and control the plasma in the process volume 18.

Further, an RF power source 136 may apply RF bias power to the substrate support 238 through an impedance match element 134. By use of the RF power source 136, the impedance match element 134 and the controller 300, the user can control the generated plasma in the process volume 18, control plasma bombardment of the substrate 240 and vary the plasma sheath thickness over the substrate surface 240A. The RF power source 136 and the impedance match element 134 may be replaced by one or more connections to ground (not shown) to ground the substrate support 238.

To control the operation of the plasma processing chamber 100, a controller 300 may be adapted to control all aspects of the complete substrate processing sequence. The controller 300 is adapted to control the impedance match elements (i.e., 130, 134, and 138), the RF power sources (i.e., 132, 136 and 140) and all other elements of the plasma processing chamber 100. The controller 300 is typically a microprocessor-based controller. The controller 300 may be configured to receive inputs from a user and/or various sensors in the plasma processing chamber and appropriately control the plasma processing chamber components in accordance with the various inputs and software instructions retained in the controller's memory. The controller 300 generally contains memory and a CPU for retaining, processing and executing various programs. The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. Support circuits may also be connected to the CPU for supporting the processor in a conventional manner. The support circuits may include cache, power supplies, clock circuits, input/output circuitry, subsystems, and the like. A program (or computer instructions) readable by the controller 300 determines which tasks are performable in the plasma processing chamber. Preferably, the program is software readable by the controller 300 and includes instructions to monitor and control the plasma process based on defined rules and input data.

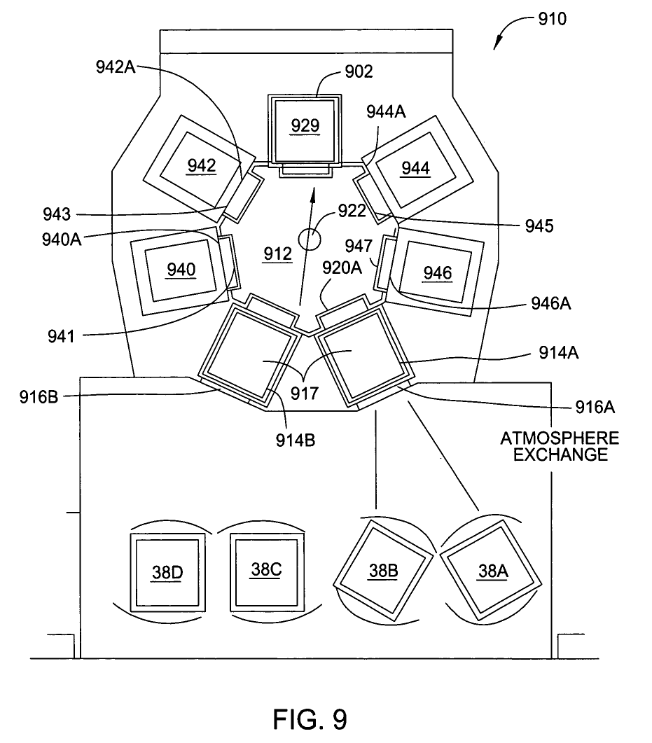

In operation, the plasma processing chamber 100 is evacuated to a predetermined pressure/vacuum by the vacuum pumping system 150 and/or the vacuum pumping system 152, so that the plasma processing chamber 100 can receive a substrate 240 from a system robot (not shown) mounted in the central transfer chamber 312 which is also under vacuum. To transfer a substrate 240 to the chamber, the slit valve (see e.g., items 941, 943, 945 and 947 in FIG. 9), which seals off the plasma processing chamber 100 from the central transfer chamber 312, opens to allow the system robot to extend through the access port 32 in the processing chamber base 202. The lift pins 52 then remove the substrate 240 from the extended system robot. The system robot then retracts from the plasma processing chamber 100 and the chamber slit valve closes to isolate the plasma processing chamber 100 from the central transfer chamber 312. The substrate support 238 then lifts the substrate 240 from the lift pins 52 and moves the substrate 240 to a desired processing position.

Once the substrate 240 has been received, the following general plasma processing steps are used to complete the processing sequence on the substrate 240. First, after the substrate 240 has been picked up off the lift pins, the substrate support 238 is moved to a desired processing position and the plasma processing chamber is evacuated to a predetermined base pressure. Once the predetermined base pressure is achieved, specific flow rate of one or more process gases are introduced into the chamber volume 17 through the gas distribution plate 64 from the gas sources 110, while the vacuum pumping system(s) continue to evacuate the chamber volume 17 until an equilibrium processing pressure is achieved. The controller 300 may adjust the processing pressure by either throttling the communication of the vacuum pumping systems (i.e., 150 and/or 152) and/or adjusting the flow rate of the process gases being introduced from the gas source 110. Once a desired pressure and gas flows are established, the respective RF power supplies may be activated to generate and control the plasma generated in the process volume 18. Power can be independently supplied to the RF coil 82, gas distribution plate 64, and/or the substrate support 238 by use of the controller 300. By varying the RF power to the RF coil 82, the gas distribution plate 64 and/or the substrate support 238, the density of the plasma generated in the process volume 18 can be varied, since the plasma ion density is directly affected by the generated magnetic and/or electric field strength. The ion density of the plasma may also be increased or decreased through adjustment of the processing pressure or the RF power delivered to the RF coil 82 and/or the gas distribution plate 64. After the various chamber processing steps have been performed on the substrate, it is then removed from the plasma processing chamber 100 by raising the lift pins 52, lowering the substrate support 238 to deposit the substrate 240 on the raised lift pins 52, opening the slit valve (not shown), extending the system robot into the chamber, lowering the lift pins 52 to deposit the substrate 240 on the system robot blade (not shown), then retracting the system robot and then closing the slit valve.

Various embodiments of the invention may be used to form a high quality gate dielectric layer using various processes, including a high density plasma oxidation (HDPO) process. Other details of the HDPO process may be described in commonly assigned U.S. patent application Ser. No. 10/990,185, filed Nov. 16, 2004, under the title “Multi-Layer High Quality Gate Dielectric For Low-Temperature Poly-Silicon TFTs”, which is incorporated herein by reference.

FIG. 9 illustrates a cluster tool 910 that may be used in connection with one or more embodiments of the invention. The cluster tool 910 is advantageous because it supports both the pre-processing steps, such as, preheating the substrate, pre-cleaning the surface of the substrate prior to processing, and post-processing steps, such as, post anneal and cool down, all in a single controlled environment. The use of a controlled environment to deposit a gate dielectric layer can be an important aspect of forming a high quality gate dielectric layer, since exposure of the substrate surface to atmospheric contamination between the HDPO layer and dielectric layer deposition steps can lead to poor electrical properties of the formed gate layer, in cases where separate chambers or separate systems are used to deposit the HDPO layer and dielectric layer.

The cluster tool 910 can be used to process substrates 240 without exposing the substrates to air. The cluster tool 910 includes a central transfer chamber 912 to which are connected load lock/cooling chambers 914A and 914B, a preheat chamber 902, and processing chambers 940, 942, 944, and 946. The central transfer chamber 912, loadlock/cooling chambers 914A and 914B, preheat chamber 902, and processing chambers 940, 942, 944, and 946 are sealed together to form a closed environment in which the system is operated at internal pressures of about 10 mTorr to about 1 Torr. Load lock/cooling chambers 914A and 914B have closable openings comprising load doors 916A and 916B to transfer the substrates 240 into the cluster tool 910. The substrate 240 may be transferred to either of the loadlock/cooling chambers 914A or 914B from one of the substrate storage positions 38A-D by use of an atmospheric robot (not shown).

Each of the loadlock/cooling chambers 914A and 914B includes a cassette 917 fitted with a plurality of shelves for supporting and cooling substrates. Cassettes 917 in loadlock/cooling chambers 914 are mounted on an elevator assembly (not shown) configured to raise and lower the cassettes 917 incrementally by the height of one shelf. The load door 916A may be opened and a substrate 240 may be placed on a shelf in cassette 917 in loadlock/cooling chamber 914A. The elevator assembly then raises cassette 917 by the height of one shelf so that an empty shelf is opposite load door 916A. Another substrate is placed on the empty shelf and the process is repeated until all of the shelves of cassette 917 are filled. At that point, load door 916A is closed and loadlock/cooling chamber 914A is evacuated to the pressure in cluster tool 910.

A slit valve 920A on the inside wall of loadlock/cooling chamber 914A adjacent to central transfer chamber 912 is then opened. Substrates 240 are transferred by means of robot 922 in central transfer chamber 912 to a preheat chamber 902 where they are preheated to a desired temperature. The substrate 240 may be heated in the preheat chamber 902 to a temperature in the range of about 250° C. to about 450° C. The substrate 240 may also be pre-heated in the load lock/cooling chamber 914 to a temperature in the range of about 250° C. to about 450° C., and thus a preheat chamber 902 is not needed to perform this function. The robot 922, which is controlled by the controller 300, is used to withdraw a substrate from cassette 917 of loadlock/cooling chamber 914A, insert the substrate onto an empty shelf in preheat chamber cassette 929 and withdraw, leaving the substrate on a shelf within preheat chamber 902. Typically, preheat chamber cassette 929 is mounted on an elevator assembly (not shown) within preheat chamber 902. After loading one shelf, preheat chamber cassette 929 is raised or lowered to present another empty shelf for access by robot 922. Robot 922 then retrieves another substrate from cassette 917 of loadlock/cooling chamber 914A.

Likewise, robot 922 may transfer all or a portion of substrates 240 from preheat chamber cassette 929 to one of four processing chambers 940, 942, 944 and 946. Each processing chamber 940, 942, 944 and 946 is optionally fitted on its inner walls 940A, 942A, 944A and 946A, respectively, with its associated slit valve 941, 943, 945 or 947, for isolation of the process gases. The processing chambers 940, 942, 944 and 946 may be plasma processing chambers 100, as described above. The plasma processing chambers in this configuration are capable of forming a HDPO layer and a conventional PECVD deposition process of a high quality gate oxide layer, all in the same chamber. This configuration may improve substrate throughput (e.g., substrates processed per hour) because the number of robot 322 handoffs between the HDPO and PECVD chambers in the cluster tool 910 may be greatly reduced. In addition, this configuration may allow many different types of process chambers and process chamber configurations to be attached to the cluster tool 910 to help resolve any possible process sequence bottlenecks.

After the substrate 240 is processed in at least one of the processing chambers 940, 942, 944 or 946, the substrate is transferred to cassette 917 of the load lock/cooling chamber 914B. The substrate may be cooled in the cool down chamber by use of a cooling surface which removes heat from the substrates mounted in the cassette 917. The cooling surface may be cooled using a conventional heat exchanging fluid flowing through a heat exchanger mounted to the cooling surface. Once the substrates has reached a desired temperature, e.g., between about 20° C. and about 150°0 C., the substrate is removed from the chamber 914B through an opened load door 916B and placed in one of the substrate storage positions 38A-D

The cluster tool 910 may also contain at least one preclean chamber mounted in one of the processing chambers 940, 942, 944, and 946 positions or the preheat chamber 929 position. The preclean chamber may be added to the system to remove any unwanted material (e.g., surface oxides, contaminants, etc.) prior to depositing the gate dielectric layer. The preclean process is a plasma cleaning process, where oxides and other contaminants are removed from the surface of the substrate by use of a light sputter etch and/or by use of a plasma etching chemistry (e.g., NF₃, CF₃, etc.). The preclean process is typically a non-selective RF plasma etching process completed using an inert gas (e.g., argon, xenon, krypton, etc.) and an inductively and/or capacitively coupled plasma driven at an RF frequency in a range between about 0.3 MHz and above 10 GHz. The RF power required to perform the preclean process may depend on the size of the chamber, the desired preclean etch rate, and the substrate bias voltage. The preclean process may be added to the cluster tool 910 processing sequence before or after the preheat step, but prior to the plasma processing step(s). The preheat and preclean processes may be completed in the same chamber. Alternatively, the preheat process may be completed in the plasma processing chamber and the preclean step may be completed prior to the preheat step. The preclean process may also be performed in situ in the plasma processing chamber 100 prior to processing.

The cluster tool 910 may further contain at least one anneal chamber mounted in one of the processing chambers 940, 942, 944, and 946 positions or the preheat chamber 929 position. The anneal chamber may be added to the system to reduce the number of defects created during the formation of the gate dielectric layer. The anneal process is a thermal process, where the substrate is processed in the anneal chamber for a desired period of time at temperatures in a range between about 400° C. and about 550° C. The annealing step may occur in an atmosphere containing nitrogen, an inert gas, or possibly a mixture of nitrogen and hydrogen, e.g., about 95% nitrogen and 5% hydrogen. The anneal process may also be performed in a vacuum. The annealing step may take about five to thirty minutes, e.g., about ten minutes. Due to the desire to increase throughput it may be desirable to provide two or more annealing chambers. After the annealing step is completed, the substrate 240 may be transferred to one of the cooling/load lock chambers 914A-B to be cooled to a handling temperature. An exemplary method of performing an annealing process and an exemplary hardware configuration in a cluster tool is further described in the U.S. patent application U.S. Pat. No. 6,610,374, entitled “Method Of Annealing Large Area Glass Substrates”, filed on Sep. 10, 2001, which is incorporated by reference herein to the extent not inconsistent with the claimed aspects and disclosure herein.

Various embodiments of the invention may be used to deposit silicon oxide by using TEOS or other silicon precursor. Embodiments of the invention may also be used to deposit other materials, such as silicon nitride, amorphous silicon, doped amorphous silicon, silicon oxynitride, amorphous carbon and silicon carbide.

While the foregoing is directed to embodiments of the present invention, other and further embodiments of the invention may be devised without departing from the basic scope thereof, and the scope thereof is determined by the claims that follow.

What is claimed is:

1. A chamber for plasma processing a substrate, comprising:
one or more chamber walls defining a plasma processing region; and
an RF transmitting device configured to transmit RF energy to the plasma processing region, wherein the RF transmitting device comprises two or more coil portions connected in parallel.

2. The chamber of claim 1, wherein the two or more coil portions comprise a first half turn coil and a second half turn coil.

3. The chamber of claim 2, further comprising an RF power source connected to an input of the first half turn coil and an input of the second half turn coil.

4. The chamber of claim 3, wherein the voltage at the input of the first half turn coil is about 180 degrees out of phase with the voltage at an output of the first half turn coil.

5. The chamber of claim 3, wherein the voltage at the input of the second half turn coil is about 180 degrees out of phase with the voltage at an output of the second half turn coil.

6. The chamber of claim 2, wherein the first half turn coil comprises an output connected to a first capacitor.

7. The chamber of claim 6, wherein the first capacitor is connected to ground.

8. The chamber of claim 2, wherein the second half turn coil comprises an output connected to a second capacitor.

9. The chamber of claim 8, wherein the second capacitor is connected to ground.

10. The chamber of claim 1, wherein the two or more coil portions comprise a first quarter turn coil, a second quarter turn coil, a third quarter turn coil and a fourth quarter turn coil.

11. The chamber of claim 1, wherein the two or more coil portions make up a single turn coil.

12. The chamber of claim 1, further comprising an impedance match network and an impedance pre-match network.

13. The chamber of claim 12, wherein the impedance pre-match network is configured to receive a single ended input from the impedance match network and provide a double ended output to the RF transmitting device.

14. The chamber of claim 12, wherein the two or more coil portions comprise a first half turn coil and a second half turn coil and the impedance pre-match network is configured to provide a first output to an input of the first half turn coil and a second output to an input of the second half turn coil.

15. The chamber of claim 14, wherein the first half turn coil comprises an output connected to a first capacitor coupled to ground and the second half turn coil comprises an output connected to a second capacitor coupled to ground, wherein the first capacitor and the second capacitor are configured to operate as a reactive element.

16. The chamber of claim 15, wherein the voltage at the input of the first half turn coil, the voltage at the input of the second half turn coil, the voltage at the output of the first half turn coil and the voltage at the output of the second half turn coil are about the same.

17. The chamber of claim 15, wherein the voltage at the input of the first half turn coil is about 180 degrees out of phase with the voltage at the output of the first half turn coil.

18. The chamber of claim 15, wherein the voltage at the input of the second half turn coil is about 180 degrees out of phase with the voltage at the output of the second half turn coil.

19. The chamber of claim 12, wherein the impedance pre-match network comprises a transformer configured to increase the impedance of the RF transmitting device by a factor of N².

20. The chamber of claim 12, wherein the impedance pre-match network is configured to transform the impedance of the RF transmitting device to a level of impedance operable by the impedance match network.

21. The chamber of claim 1, further comprising a gas distribution plate coupled to an RF power source.

22. A chamber for plasma processing a substrate, comprising:
one or more chamber walls defining a plasma processing region; and
an RF transmitting device configured to transmit RF energy to the plasma processing region, wherein the RF transmitting device comprises a first coil portion and a second coil portion connected in parallel, wherein each of the first coil portion and the second coil portion is a half turn coil and the voltage at an input of the first coil portion and the voltage at an input of the second coil portion are about the same.

23. The chamber of claim 22, wherein the voltage at the input of the first coil portion is about 180 degrees out of phase with the voltage at an output of the first coil portion.

24. The chamber of claim 22, wherein the voltage at the input of the second coil portion is about 180 degrees out of phase with the voltage at an output of the second coil portion.

25. A chamber for plasma processing a substrate, comprising:
one or more chamber walls defining a plasma processing region;
an RF transmitting device configured to transmit RF energy to the plasma processing region, wherein the RF transmitting device comprises a first coil portion and a second coil portion connected in parallel, wherein each of the first coil portion and the second coil portion is a half turn coil;
an impedance pre-match network coupled to the RF transmitting device; and
an impedance match network coupled to the impedance pre-match network, wherein the impedance pre-match network is configured to receive a single ended input from the impedance match network and provide a double ended output to the RF transmitting device.

26. The chamber of claim 25, wherein the impedance pre-match network comprises a transformer configured to increase the impedance of the RF transmitting device by a factor of N².

27. The chamber of claim 25, wherein the impedance pre-match network is configured to transform the impedance of the RF transmitting device to a level of impedance operable by the impedance match network.

28. A method for transmitting RF energy to a plasma processing region, comprising:
providing an RF transmitting device having a first coil portion connected to a second coil portion connected in parallel, wherein the RF transmitting device is coupled to a chamber having one or more walls defining the plasma processing region;
applying RF power to the first coil portion; and
applying RF power to the second coil portion.

29. The method of claim 28, wherein each of the first coil portion and the second coil portion is a half turn coil.
